(19) United States
(12) Patent Application Publication
(10) Pub. No.: US 2012/0133034 A1
(43) Pub. Date: May 31, 2012

(54) LEAD FRAME FOR ELECTRONIC COMPONENT AND METHOD OF MANUFACTURING THE SAME

(75) Inventors: Ryoutarou Imura, Kyoto (JP); Akira Asada, Kyoto (JP)

(73) Assignee: PANASONIC CORPORATION, Osaka (JP)

(21) Appl. No.: 13/213,882

(22) Filed: Aug. 19, 2011

(30) Foreign Application Priority Data
Nov. 25, 2010 (JP) 2010-261874

(51) Int. Cl. H01L 23/495; H01R 43/00

(52) U.S. Cl. 257/666; 29/827; 257/E23.031

(57) ABSTRACT

In a lead frame for an electronic component according to the present invention, a metal plate 3 is extended by a punch 5 into a hole 4 formed on a metal plate 2 and the two metal plates are connected on the inner surface of the hole 4, thereby improving a bonding strength while keeping the small size and thickness of the lead frame with a simple method.

### REFERENCE TO RELATED APPLICATIONS

The disclosure of Japanese Patent Application No. 2010-261874 filed Nov. 25, 2010 including specification, drawings and claims is incorporated herein by reference in its entirety.

### FIELD OF THE INVENTION

The present invention relates to a lead frame for an electronic component and a method of manufacturing the same, the lead frame including at least two stacked metal plates.

### BACKGROUND OF THE INVENTION

In the case where a lead frame for an electronic component is fabricated by joining at least two metal plates, the metal plates are bonded by caulking. The at least two metal plates may be joined by other methods such as welding and bonding but these joining methods require a welding material or a bonding material, whereas caulking does not particularly require any other members, achieving low production cost.

FIGS. 5A and 5B are process sectional views showing a method of manufacturing a lead frame for an electronic component according to the related art.

As shown in FIG. 5A, in a lead frame for an electronic component according to the related art, a lead frame 22 having a hole 24 and a lead frame 23 having a hole 26 are stacked. As shown in FIG. 5B, the two lead frames are joined to each other by stamping with a caulking punch 25 in a state in which the holes are aligned with each other (for example, see Japanese Patent Laid-Open No. 8-215778).

Alternatively, a protrusion may be formed beforehand on one of the lead frames and a hole may be formed on the other lead frame. In this case, the lead frames are set in a mold so as to insert the protrusion into the hole and then the protrusion is flattened with a working punch, so that a caulked joint is completed.

FIGS. 6A to 6D are process sectional views showing a method of manufacturing a lead frame for an electronic component, in which a caulked joint is made using a protrusion according to the related art.

As shown in FIGS. 6A to 6D, first, a protrusion 36 is provided on a lead frame 32 and then the protrusion 36 is inserted into a hole 34 formed on a lead frame 33 (FIG. 6A). Next, a caulking punch 35 is moved down as shown in FIG. 6B and then the protrusion 36 is flattened by stamping as shown in FIG. 6C, so that a caulked joint is completed (FIG. 6D).

### DISCLOSURE OF THE INVENTION

In the lead frame for an electronic component according to the related art shown in FIGS. 5A and 5B, however, the at least two lead frames are joined with a low bonding strength and thus may be separated from each other in the processing of a downstream process or in use. Additionally, it is quite difficult to align the caulking holes 24 and 26 formed on the lead frames when the at least two lead frames are joined by caulking. In the lead frame for an electronic component according to the related art shown in FIGS. 6A to 6D, the protrusion 36 is provided on the lead frame 32. Although the protrusion 36 has a small thickness in stamping when the caulked joint is made, the thickness of the protrusion 36 is added to the total thickness of the at least two lead frames that have been stacked and joined to each other, leading to some degradation of the roles of electronic components having been recently reduced in size and weight.

As has been discussed, in the lead frame for an electronic component according to the related art, one metal plate is simply pressed with a punch and is stacked on the other metal plate. Disadvantageously, the metal plates are joined by caulking with a small strength and may be separated from each other. Moreover, it is quite difficult to align the at least two metal plates with parts in a mold in a caulking process, causing a misalignment when a caulked joint is made. Thus a desired joint may not be obtained, resulting in a lower caulking strength. Furthermore, in the laminated structure of the multiple metal plates, the protrusion 36 for caulking is left in the lead frame for an electronic component after the caulked joint is made, increasing the thickness of the lead frame for an electronic component. Thus the electronic component may not be reduced in thickness, leading to problems in packaging.

An object of the present invention is to improve a bonding strength while securing a reduction in size and thickness with a simple method.

In order to attain the object, a method of manufacturing a lead frame for an electronic component according to the present invention includes: a first placing step of placing a first metal plate on a die, the first metal plate having a hole; a second placing step of placing a second metal plate on a surface of the first metal plate with the hole formed on the surface; and a processing step of inserting a punch into the hole from above the second metal plate, wherein the second metal plate is extended into the hole and an intermetallic bond is formed between the first metal plate and the second metal plate on the inner surface of the hole.

Preferably, the punch contains first protrusions capable of protruding from the side of the punch and an operation pin used for protruding the first protrusions, the first protrusions are protruded from the side of the punch by the operation pin after the processing step, so that the second metal plate is protruded into engagement with the first metal plate.

Moreover, a plurality of protruding shapes may be formed on the side of the punch so as to be inserted into the hole and a plurality of projecting portions are formed on the second metal plate by the protruding shapes such that the second metal plate is engaged into the first metal plate.

Furthermore, second protrusions capable of protruding are retracted on a surface of the die with the first metal plate placed on the surface, and after the processing step, the intermetallic bond may be accelerated by protruding the second protrusions to form a recessed portion around a region directly below the hole on the contact surface of the first metal plate with the die.

Moreover, a lead frame for an electronic component according to the present invention includes: a first metal plate having a hole on a first major surface; and a second metal plate joined in contact with at least the inner surface of the hole and a part of the first major surface, wherein an intermetallic bond is formed between the first metal plate and the second metal plate on the inner surface of the hole.

Preferably, the second metal plate is protruded on the inner surface of the hole into engagement with the first metal plate.

The lead frame for an electronic component may further include a recessed portion formed around a region directly below the hole on the contact surface of the first metal plate with the die.

The hole may be formed by penetrating the first metal plate.

### BRIEF DESCRIPTION OF THE DRAWINGS

FIG. 1A is a process sectional view showing a method of manufacturing a lead frame for an electronic component according to a first embodiment;

FIG. 1B is a process sectional view showing the method of manufacturing the lead frame for an electronic component according to the first embodiment;

FIG. 1C is a process sectional view showing the method of manufacturing the lead frame for an electronic component according to the first embodiment;

FIG. 1D is a process sectional view showing the method of manufacturing the lead frame for an electronic component according to the first embodiment;

FIG. 2A is a process sectional view showing a method of manufacturing a lead frame for an electronic component according to a second embodiment;

FIG. 2B is a process sectional view showing the method of manufacturing the lead frame for an electronic component according to the second embodiment;

FIG. 2C is a process sectional view showing the method of manufacturing the lead frame for an electronic component according to the second embodiment;

FIG. 2D is a process sectional view showing the method of manufacturing the lead frame for an electronic component according to the second embodiment;

FIG. 3A is a process sectional view showing a method of manufacturing a lead frame for an electronic component according to a third embodiment;

FIG. 3B is a process sectional view showing the method of manufacturing the lead frame for an electronic component according to the third embodiment;

FIG. 3C is a process sectional view showing the method of manufacturing the lead frame for an electronic component according to the third embodiment;

FIG. 3D is a process sectional view showing the method of manufacturing the lead frame for an electronic component according to the third embodiment;

FIG. 4A is a process sectional view showing a method of manufacturing a lead frame for an electronic component according to a fourth embodiment;

FIG. 4B is a process sectional view showing the method of manufacturing the lead frame for an electronic component according to the fourth embodiment;

FIG. 4C is a process sectional view showing the method of manufacturing the lead frame for an electronic component according to the fourth embodiment;

FIG. 4D is a process sectional view showing the method of manufacturing the lead frame for an electronic component according to the fourth embodiment;

FIG. 5A is a process sectional view showing a method of manufacturing a lead frame for an electronic component according to the related art;

FIG. 5B is a process sectional view showing the method of manufacturing the lead frame for an electronic component according to the related art;

FIG. 6A is a process sectional view showing a method of manufacturing a lead frame for an electronic component by forming a caulked joint with a protrusion according to the related art;

FIG. 6B is a process sectional view showing the method of manufacturing the lead frame for an electronic component by forming the caulked joint with the protrusion according to the related art;

FIG. 6C is a process sectional view showing the method of manufacturing the lead frame for an electronic component by forming the caulked joint with the protrusion according to the related art; and

FIG. 6D is a process sectional view showing the method of manufacturing the lead frame for an electronic component by forming the caulked joint with the protrusion according to the related art.

### DESCRIPTION OF THE EMBODIMENTS

Generally, a lead frame for an electronic component includes a stepped member, on which only a heat dissipation part has a large thickness, to obtain a heat dissipation function. However, the stepped member in a special form has to be fabricated in a larger number of steps with higher production cost as compared with an ordinary plate. For this reason, two metal plates varied in thickness are prepared such that one of the metal plates has a large thickness to obtain a heat dissipation function and the other metal plate has a function other than heat dissipation. The two metal plates are joined by caulking, so that a lead frame for an electronic component with the heat dissipation function can be formed in a smaller number of steps and with lower production cost than in the fabrication of the stepped member.

Moreover, a lead frame for an electronic component with various functions may be formed by joining two different metal plates by caulking. For example, in the case where heat dissipation and insulation are necessary on a lead frame for an electronic component in a package containing two chips, it is difficult to obtain heat dissipation and insulation from a single material. For this reason, a metal plate having excellent heat dissipation and a metal plate having high insulation are prepared and the two metal plates are joined by caulking, so that a lead frame for an electronic component can be fabricated with heat dissipation and insulation. The multiple metal plates having different functions are joined thus by caulking, so that a lead frame for an electronic component can be fabricated with multiple functions.

Additionally, in the case where only a region of a lead frame for an electronic component requires a different function from the other region, multiple metal plates can be effectively used. For example, in the case where a region of a lead frame for an electronic component requires plating and the other region does not require plating in the fabrication of the lead frame composed of a single metal plate, plating has to be selectively performed or plating has to be removed in the undesired region after the overall lead frame is plated. However, in the case where two metal plates are separately fabricated and are joined by caulking, only one of the metal plates is entirely plated and the other metal plate is not plated in the fabrication of the metal plates. The two metal plates are joined by caulking to fabricate a lead frame for an electronic component such that the plated metal plate is disposed in a region to be plated. Thus an undesired area is not plated and the cost of plating materials can be reduced.

The present invention provides a lead frame for an electronic component, the lead frame being formed by joining multiple metal plates. A feature of the present invention is that at a joint of the metal plates, one of the metal plates is extended into a hole formed on the other metal plate and the metal plates are joined on the inner surface of the hole, which can improve a bonding strength while keeping the small size and thickness of the lead frame with a simple method.

The following will specifically describe examples of a configuration for joining two lead frames that are metal plates. The number of metal plates constituting the lead frame for an electronic component is not limited to two as long as two of the metal plates are joined as described below.

### First Embodiment

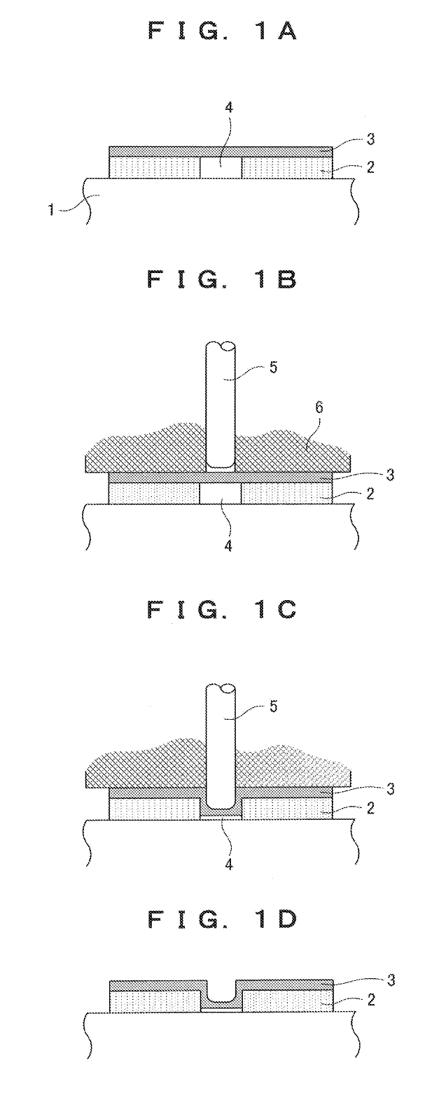

First, referring to FIGS. 1A to 1D, the following will specifically describe a method of manufacturing a lead frame for an electronic component according to a first embodiment.

FIGS. 1A to 1D are process sectional views showing the method of manufacturing the lead frame for an electronic component according to the first embodiment.

In FIG. 1A, a lead frame 2 that is a first metal plate having a hole 4 is placed on a die 1 in a mold for a caulked joint and a lead frame 3 that is a second metal plate is placed on the lead frame 2. At this point, the center of the hole 4 formed on the stacked lead frame is aligned with the center of a punch 5 for a caulked joint.

Next, as shown in FIG. 1B, the punch 5 for a caulked joint is moved down while the two stacked lead frames 2 and 3 are pressed with a guide 6. At the moment when the descending punch 5 comes into contact with the second lead frame 3, the second lead frame 3 starts deformation on the hole 4, and then the second lead frame 3 is deformed and moved into the hole 4 of the first lead frame 2 while being affected by the end shape of the punch 5. As shown in FIG. 1C, the punch 5 is moved down to a predetermined bottom dead center. The deformation is completed when the punch 5 reaches the bottom dead center. At this point, the two lead frames 2 and 3 are mechanically joined to form the lead frame for an electronic component in a state in which the lead frame 3 has a plastic deformation part fit into the hole 4 (FIG. 1D). The lead frame 3 being deformed by the descending punch 5 moves to the lead frame 2. The lead frame 2 is also deformed according to the metal movement of the lead frame 3. At the joint of the inner surface of the hole 4 of the lead frame 2 and the plastic deformation part of the lead frame 3, metal molecules move between the two lead frames. The punch 5 further moving downward generates an interactive stress between the lead frames 2 and 3, so that the metal molecules actively move between the lead frames 2 and 3 to improve a bonding strength. At this point, at the edge of the hole 4 of the lead frame 2, the metal of the lead frame 3 is pressed by the punch 5 and starts deformation. The metal deformed from the edge is pressed onto the side of the hole 4 of the lead frame 2 along the pressed punch 5. The metal of the lead frame 3 at a deformed point is joined with the metal of the hole 4 of the lead frame 2 while covering the metal of the hole 4. Particularly, the metals of the lead frames are bound with each other in a complicated manner at the edge serving as a deformation starting point, so that the joint is strengthened.

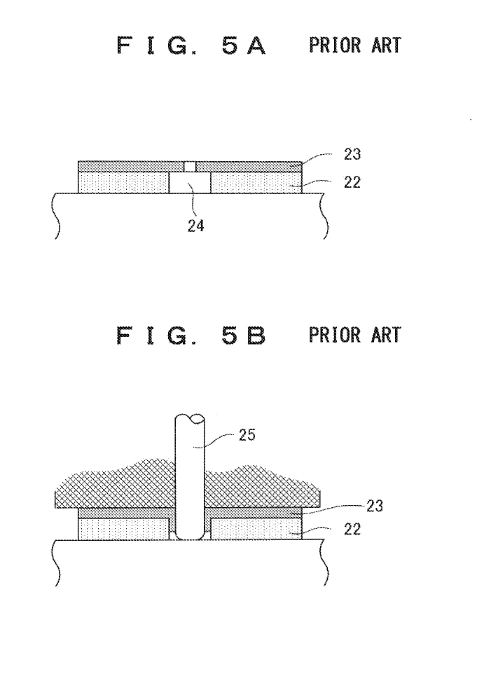

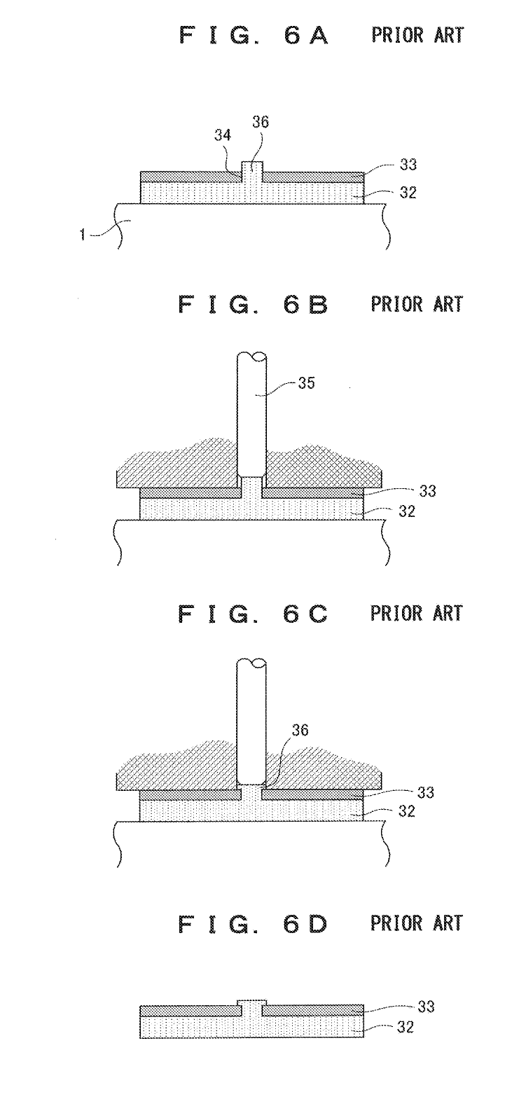

In the present invention, the hole is not formed like the hole of the lead frame 23 shown in FIG. 5A of the related art, in order to increase a metal loading for joining the lead frames. Furthermore, in the present invention, the metal is disposed in the hole area of the related art, increasing the total metal loading. Thus the metal loading increases and a junction area for joining the two metal plates by caulking is extended, achieving a higher bonding strength.

At this point, the thickness of the lead frame after a caulked joint is made is equal to the total thickness of the two lead frames. The second lead frame 3 is moved by the punch 5 while the depth of the punch is properly adjusted to prevent the second lead frame 3 from protruding from a contact surface with the die 1 and leading to a larger thickness.

The punch 5 and the hole 4 may have any shapes but it is preferable that the punch 5 is cylindrical and the hole 4 has a circular opening. Furthermore, the diameter of the punch 5 is determined by subtracting the total required thickness of the metal plate extended on the inner surface of the hole 4 from the inside diameter of the hole 4.

In the lead frame for an electronic component and the method of manufacturing the same according to the present invention, the lead frame being formed by joining the at least two lead frames that are metal plates, one of the metal plates is extended by the punch into the hole formed on the other metal plate and the two metal plates are connected on the inner surface of the hole. The joint surface of the metal plates is formed thus on the inner surface of the hole by the punch, so that a stress on the joint surface forms an intermetallic bond between the metal plates so as to improve the bonding strength. At this point, the metal plates do not have to be aligned with each other, thereby easily improving the bonding strength. Although a protrusion is formed in the related art, a protrusion forming process is not necessary in the formation of the metal plates according to the present invention, thereby more easily improving the bonding strength. Since the joint surface is formed in the hole, the small size and thickness of the lead frame can be kept without affecting the outside shape of the lead frame for an electronic component. Moreover, a higher bonding strength facilitates handling in a downstream process. In a region where the at least two metal plates are joined, the metal plates are joined without forming any gap, so that an electrical resistance decreases at the joint and electrical conductivity can be improved on a caulked lead.

The lead frames 2 and 3 are metal plates, each having at least one terminal portion or element mounting portion according to the shape of the lead frame for an electronic component.

### Second Embodiment

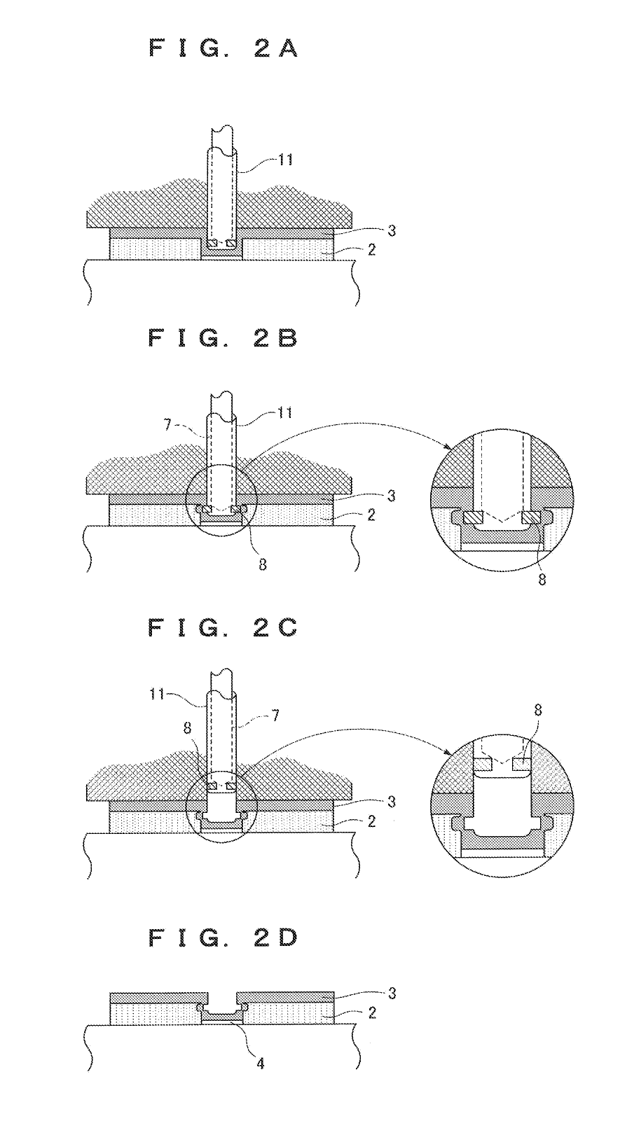

FIGS. 2A to 2D are process sectional views showing a method of manufacturing a lead frame for an electronic component according to a second embodiment.

In the present embodiment, instead of the punch 5 of the first embodiment, a punch 11 is used that includes at least one protrusion 8 capable of protruding from the side of the punch and an operation pin 7 that protrudes the at least one protrusion 8. Before a manufacturing process, the at least one protrusion 8 is retracted in the punch 11 so as to be flush with the side of the punch 11. The at least one protrusion 8 can be protruded from the side of the punch 11 by the operation pin 7. The punch 11 has a hollow part that exposes the inside of the at least one protrusion 8. The operation pin 7 is stored in the hollow part so as to move in parallel with the lowering direction of the punch 11. The operation pin 7 has a tapered end at a contact point with the at least one protrusion 8. The operation pin 7 is moved down in the punch 11, so that the tapered portion can press the at least one protrusion 8.

The same process as in the first embodiment is performed until the state of FIG. 10 in which lead frames 2 and 3 are joined by the punch. Then, as shown in FIG. 2A, the two lead frames 2 and 3 are joined by the punch 11 for a caulking joint. After that, as shown in FIG. 2B, the operation pin 7 contained in the punch 11 is moved down. The end of the operation pin 7 has a tapered shape along which the at least one protrusion 8 contained like the operation pin 7 in the punch 11 is protruded to the two lead frames 2 and 3 having been just joined by caulking. The two lead frames 2 and 3 are deformed into a wedge such that the deformed portion of the lead frame 3 is engaged into the lead frame 2, increasing the joint area of the two lead frames 2 and 3. The joint of the lead frames is deformed with a larger joint area, so that a bonding strength improves and a vertical movement that may separate the two lead frames 2 and 3 can be suppressed by forming asperities. After the formation of protruding shapes for improving the bonding strength, as shown in FIG. 2C, the operation pin 7 is moved up to retract the at least one protrusion 8. After that, the punch 11 for a caulking joint is moved up, so that the lead frame for an electronic component is formed as shown in FIG. 2D in which an intermetallic bond is formed between the lead frames 2 and 3 on the inner surface of a hole 4 and the lead frame 3 is engaged like a wedge into the lead frame 2 on the joint surface of the lead frames.

The at least one protrusion 8 contained in the punch 11 is protruded thus to engage the lead frame 3 like a wedge into the lead frame 2 on the joint surface of the inner surface of the hole 4, achieving an anchor effect; meanwhile, the small size and thickness of the lead frame is kept with a simple method. Thus the bonding strength of the lead frames 2 and 3 can be more improved than in the first embodiment.

### Third Embodiment

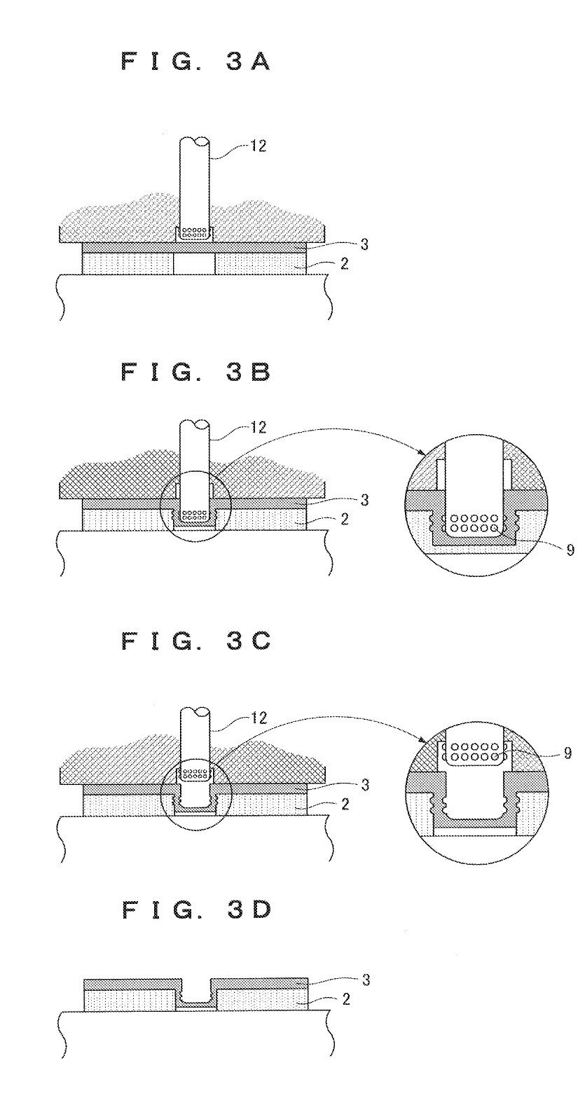

FIGS. 3A to 3D are process sectional views showing a method of manufacturing a lead frame for an electronic component according to a third embodiment. A joining method for improving the strength of a caulked joint will be described as in the embodiment illustrated in FIGS. 2A to 2D.

As shown in FIG. 3A, two lead frames 2 and 3 are joined by a punch 12 for a caulked joint. At this point, the lead frames 2 and 3 are joined by caulking while the metallic materials of the lead frames 2 and 3 are deformed by a plurality of protrusions 9 that are disposed on the punch 12 as shown in FIG. 3B. The protrusions 9 move the metallic part of the lead frame 3; meanwhile, the lead frame 2 is deformed according to the movement. As in the measure for improving a strength in FIGS. 2A to 2D, the two lead frames 2 and 3 are also deformed at the joint of the lead frames, a bonding strength increases with a joint area, and a vertical movement that may separate the two lead frames 2 and 3 can be suppressed by forming asperities. After that, as shown in FIG. 3C, the punch 12 is lifted. In this case, when the punch 12 for a caulked joint moves down to a bottom dead center, the punch 12 may be rotated to further deform the two lead frames 2 and 3 and the joint, so that the bonding strength can increase with the joint area. Alternatively, the punch 12 may be moved down while being rotated and vibrated, so that the bonding strength can be similarly improved.

FIGS. 3A to 3D show a cross section at a point where the protrusions are not provided at the bottom dead center when the punch is moved down. At a point having the protrusions, a continuous groove is formed along the protrusions on the side of the punch 12. In the case where the protrusions are not provided at the bottom dead center as shown in FIGS. 3A to 3D, the punch 12 is rotated later to form asperities at the joint.

Finally, the punch 12 is pulled out, so that the lead frame for an electronic component is formed with the asperities shaped like grooves on the joint surface of the lead frames.

### Fourth Embodiment

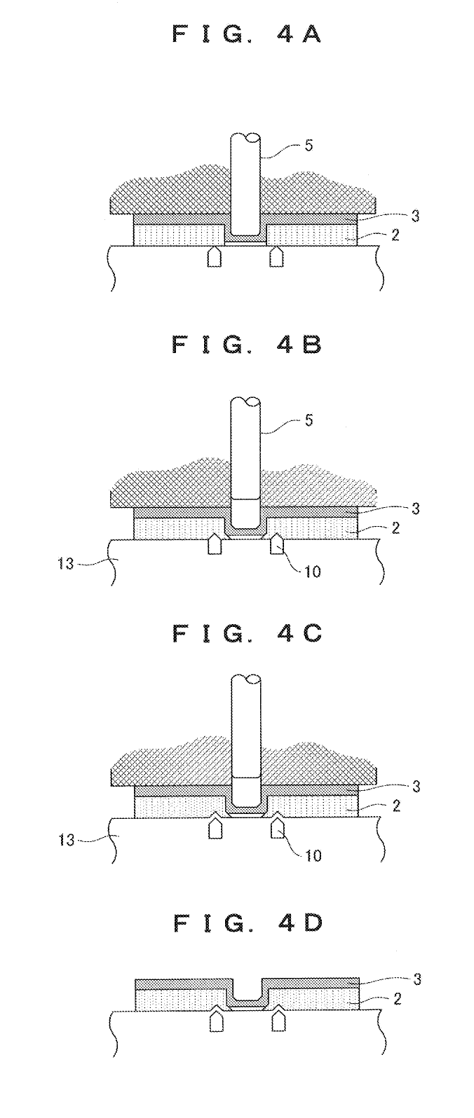

FIGS. 4A to 4D are process sectional views showing a method of manufacturing a lead frame for an electronic component according to a fourth embodiment. A joining method for improving the strength of a caulked joint will be described as in the second and third embodiments.

In the present embodiment, the die 1 of the first embodiment is replaced with a die 13 that includes protrusions 10 capable of protruding in a region surrounding a hole 4 on the contact surface of the die with a lead frame 2.

First, as shown in FIG. 4A, the lead frame 2 and a lead frame 3 are joined by a punch 5 for a caulked joint as in the first embodiment. Next, as shown in FIG. 4B, the punch 5 is lifted after stamping. In this state, the protrusions 10 retracted in the die 13 are protruded to the lead frame 2. The protrusions 10 deform the lead frame 2. The protrusions 10 may be protruded so as to deform the lead frame 3. The deformation further increases a joint area at the joint of the lead frames, which improves a bonding strength. Moreover, the protrusions 10 may deform the joint into a wedge to further increase the bonding strength between the lead frames 2 and 3 with an anchor effect. After that, as shown in FIG. 4C, the protrusions 10 protruded from the die 13 are retracted into the die 13. As shown in FIG. 4D, a joining process of improving the bonding strength is completed, so that the lead frame for an electronic component is formed.

As has been discussed, the contact surface of the lead frame 2 with the die 13 is deformed by the protrusions 10, so that an intermetallic bond is accelerated on the joint surface of the lead frames and the bonding strength between the lead frames can be easily improved without extending outside dimensions. Furthermore, asperities like wedges on the joint surface can further improve the bonding strength between the lead frames.

In this explanation, the protrusions are formed from the back side of the lead frame 2 in the joining of the first embodiment. The protrusions may be formed from the back side of the lead frame 2 in the joining of the second and third embodiments.

In the explanation of the embodiments, the hole 4 formed on the lead frame 2 penetrates the front and back sides of the lead frame 2. The hole may be closed on the back side of the lead frame 2 with respect to the contact surface of the lead frame 2 with the lead frame 3.

What is claimed is:

1. A method of manufacturing a lead frame for an electronic component, the method comprising:
a first placing step of placing a first metal plate on a die, the first metal plate having a hole;
a second placing step of placing a second metal plate on a surface of the first metal plate with the hole formed on the surface; and
a processing step of inserting a punch into the hole from above the second metal plate, wherein the second metal plate is extended into the hole and an intermetallic bond is formed between the first metal plate and the second metal plate on an inner surface of the hole.

2. The method of manufacturing a lead frame for an electronic component according to claim 1, wherein the punch contains first protrusions capable of protruding from a side of the punch and an operation pin used for protruding the first protrusions,
the first protrusions are protruded from the side of the punch by the operation pin after the processing step, so that the second metal plate is protruded into engagement with the first metal plate.

3. The method of manufacturing a lead frame for an electronic component according to claim 1, wherein a plurality of protruding shapes are formed on a side of the punch so as to be inserted into the hole, and a plurality of projecting portions are formed on the second metal plate by the protruding shapes such that the second metal plate is engaged into the first metal plate.

4. The method of manufacturing a lead frame for an electronic component according to claim 1, wherein second protrusions capable of protruding are retracted on a surface of the die with the first metal plate placed on the surface, and
after the processing step, the intermetallic bond is accelerated by protruding the second protrusions to form a recessed portion around a region directly below the hole on a contact surface of the first metal plate with the die.

5. The method of manufacturing a lead frame for an electronic component according to claim 1, wherein the hole penetrates the first metal plate.

6. A lead frame for an electronic component, comprising:
a first metal plate having a hole on a first major surface; and
a second metal plate joined in contact with at least an inner surface of the hole and a part of the first major surface,
wherein an intermetallic bond is formed between the first metal plate and the second metal plate on the inner surface of the hole.

7. The lead frame for an electronic component according to claim 6, wherein the second metal plate is protruded on the inner surface of the hole into engagement with the first metal plate.

8. The lead frame for an electronic component according to claim 6, further comprising a recessed portion formed around a region directly below the hole on a contact surface of the first metal plate with the die.

9. The lead frame for an electronic component according to claim 6, wherein the hole penetrates the first metal plate.
